(19) United States
(12) Patent Application Publication
(10) Pub. No.: US 2007/0267145 A1
(43) Pub. Date: Nov. 22, 2007

(54) Sample table and plasma processing apparatus provided with the same

(76) Inventors: Hiroho Kitada, Kudamatsu (JP); Kazunori Nakamoto, Kudamatsu (JP); Masakazu Isozaki, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/513,367

(22) Filed: Aug. 31, 2006

(30) Foreign Application Priority Data
May 19, 2006 (JP) 2006-140079

(51) Int. Cl. H01L 21/306; C23C 16/00

(52) U.S. Cl. 156/345.51; 118/728

(57) ABSTRACT

A plasma processing apparatus includes: two disk-shaped members that are disposed inside the sample table and vertically connected; coolant grooves that are respectively disposed in the outer circumference side and the central side of the upper disk-shaped member and inside which coolants flow; a ring-shaped groove for suppressing heat transfer between these coolant grooves that is disposed between these coolant grooves; a fastening unit that fastens the upper disk-shaped member and the lower disk-shaped member respectively in plural positions of the outer circumference side of the coolant groove of the outer circumference side, and in plural positions of the inner circumference side of the ring-shaped groove; and pusher pins for carrying in/out a sample to the sample mounting surface, wherein the fastening unit of the inner circumference side of the ring-shaped groove and the pusher pins are disposed on a circle circumference within a range of 47 to 68% of the radius of the sample.

### CLAIM OF PRIORITY

The present application claims priority from Japanese application serial JP 2006-140079 filed on May 19, 2006, the content of which is hereby incorporated by reference into this application.

### BACKGROUND OF THE INVENTION

The present invention relates to a plasma processing apparatus that uses plasma and processes samples such as semiconductor wafers, and more particularly to a plasma processing apparatus that includes a unit that holds a sample to a sample table during processing of the sample, and a unit that controls the temperature of the sample table.

A processing chamber that uses plasma etching includes an evacuating system such as an evacuation pump for decompression. Because of the evacuation operation, the outer circumference and the central portion of a sample are different in a process gas distribution and a reaction product distribution according to etching, and to obtain uniform etching performance, it is desirable that temperatures on the sample surface are higher at the center and lower in the outer circumference. Conventionally, a method has been known which causes a temperature gradient to occur on a sample mounting surface holding a sample, and at the same time, causes a temperature gradient to occur in the sample through a gas for heat transfer introduced to the back surface of the sample. On the inside of the sample table, flow paths for making a coolant flow are provided independently in an inner portion and an outer portion, and a temperature gradient is caused to occur on the sample mounting surface of the sample table by feeding coolants set to different temperatures.

A higher thermal resistance between the inner flow path and the outer flow path causes a temperature difference between the inside and the outside to occur more easily, and places less burden on a coolant temperature control unit. As a method of increasing the thermal resistance, a structure in which a heat insulating layer is provided between the inner flow path and the outer flow path is known. It is desirable that the inside of the heat insulating layer is evacuated an atmosphere, and such the evacuated component can be formed by the joining method by brazing or the like. When the heat insulating layer is larger in the radial direction and the height direction of the sample table, a higher heat insulating effect is produced. Therefore, the thickness of metal around the heat insulating layer becomes thin, and as the sample table that receives internal pressure summing coolant pressure and atmosphere pressure, the heat insulating layer portion is weak in strength. When the sample table is manufactured by the joining method by brazing and the anodic bonding method (EB), the rigidity of the entire sample table is easily secured because of face bonding. The materials of the sample table are dominantly titanium and SUS because of low thermal conductivity.

In some sample tables, without using the joining method by brazing and the anodic bonding method, a heat insulating layer of a evacuated atmosphere is formed by the non-bonding method. For example, as described in Japanese Patent Laid-Open Nos. 2000-216140 and 2003-243371, in a sample table formed of a single metallic plate provided with a sprayed film, coolant grooves, and a heat insulating layer that constitute the sample mounting surface, the outer-most circumference portion is fastened from the upper surface to the base part of the sample table by fastening tools such as bolts. In this case, since a large heat insulating layer is not provided because of strength constraints, obtained temperature performance is low. Generally, in process cases not requiring a large temperature gradient or process cases of a single temperature distribution, sample tables by the non-bonding method are often used.

To increase the efficiency on heat transferring or temperature controlling of the sample table, it is effective that a heat insulating layer is expanded and the distance between coolant grooves and the sample mounting surface is reduced. In the case of a sample table manufactured by the non-bonding method, when the sample table receives an internal pressure summing coolant pressure and atmosphere pressure, the sample table deflects, the flatness of the wafer mounting surface is impaired, a leak amount of back surface gas is large because a sample cannot be secured by electrostatic chucking or the like, leading to accidents. Therefore, it is necessary to determine the size of coolant grooves and a heat insulating layer while observing strength constraints. In short, in comparison under connection to a same coolant control unit, obtained temperature performance are lower in a non-bonding method than those of a sample table manufactured by a bonding method.

In terms of temperature performance and rigidity, the joining method by brazing and anodic bonding method are more advantageous. However, depending on materials, in manufacturing a sample table, generally, the bonding method is two or three times more expensive than the non-bonding method.

Recently, with the rapid development of high integration of a semiconductor device, high yields and stability have been strongly demanded for semiconductor manufacturing equipment. An improvement in the performance and the stability of members such as a sample table that directly influence etching performance are required. Since the sample table rules the temperature of a sample, temperature performance must be stable regardless of the lapse of time, and direct contact with a sample imposes the problem of generating foreign matter due to contact.

Particularly, when plasma is processed without a sample and a processing chamber is subjected to plasma cleaning, the surface state of the sample table changes with the lapse of time, and a change of contact temperature passage rate and an increase in contact with contaminating matter are apt to occur. As a solution, the sample table is periodically replaced by a new, a reproduced, or a cleaned sample table. Frequent executions of these operations lead to maintaining stable performance. Therefore, it is desired for the sample table an excellent capability of replacement, and to be inexpensive at the same time. When the sprayed film constituting the sample mounting surface has come to an end of its life and must be replaced by a new one, in the case of the sample table in which a heat insulating layer is formed by the bonding method, the base part and like as well as the sprayed film must be replaced as an unit, resulting in higher running costs. Thus, in comparison with a sample table manufactured by the non-bonding method, a sample table manufactured by the bonding method is excellent in rigidity and temperature performance, but has problems in high manufacturing costs and running costs.

### SUMMARY OF THE INVENTION

An object of the present invention is to provide a sample table of high rigidity and high temperature performance in which a heat insulating layer of a evacuated atmosphere is disassemblably manufactured by a non-bonding method, and a plasma processing apparatus including the same.

The present invention is a plasma processing apparatus including a processing chamber evacuated by an evacuating system, a sample table disposed within the processing chamber in which a sample mounting surface is provided, and pusher pins for carrying in/out a sample to the sample mounting surface. The plasma processing apparatus includes: a first disk-shaped member and a second disk-shaped member that are disposed inside the sample table and vertically connected; an outer circumference coolant groove and an inner coolant groove that are respectively disposed in the outer circumference side and the central side of the first disk-shaped member and inside which coolants flow; a ring-shaped groove for suppressing heat transfer between these inner and outer coolant grooves that is disposed between these inner and outer coolant grooves; a first fastening unit that fastens the first disk-shaped member and the second disk-shaped member in the outer circumference side of the ring-shaped groove; and a second fastening unit that fastens the first disk-shaped member and the second disk-shaped member in the inner circumference side of the ring-shaped groove.

The pusher pins and the second fastening unit are disposed further in a concentric region at the inner circumference side than the ring-shaped groove with respect to the sample table, and the inner coolant groove is disposed further at the central side of the sample table than the concentric region.

According to other aspect of the present invention, the concentric region is within a range of 47 to 68% of the radius of the sample.

According to the present invention, a sample table of high rigidity and high temperature performance in which a heat insulating layer of a evacuated atmosphere is formed by fastening, and a plasma processing apparatus including the same can be provided.

### BRIEF DESCRIPTION OF THE DRAWINGS

FIG. 1 is a vertical cross-sectional drawing for explaining the structure of a vacuum processing chamber of one embodiment of the present invention;

FIG. 2 is a vertical cross-sectional drawing showing details of the inside of the sample table of one embodiment of the present invention;

FIG. 3 is a vertical cross-sectional drawing showing an enlarged view of a part of FIG. 2;

FIG. 4 is a drawing a cross section taken along the A-A line of FIG. 2;

FIG. 5 is an assembly exploded view of the sample table of one embodiment of the present invention;

FIG. 6 is a drawing showing the overall construction of a vacuum processing apparatus employing one embodiment of the present invention;

FIG. 7 is an assembly exploded view of the sample table of another embodiment;

FIG. 8 shows the arranging positions of the pusher pins within the sample table of the present invention and the arranging positions of bolts fastening upper and lower members constituting base materials of the sample table as percentage positions to the size of the radius of the wafer;

FIG. 9 is a graph indicating changes of the magnitude of equivalent stress for the percentage of the arranging positions of the pusher pins, the horizontal axis showing the percentages of the positions of pusher pins in the radial direction of a wafer as a substrate-shaped sample to be processed for a wafer radius value, and the vertical axis showing values standardized as equivalent stress for a maximum value of stress occurring in the wafer during pushup operation of pusher pins disposed in each position (percentage);

FIG. 10 is a graph indicating a relation between the percentage of bolt positions and standard values of deformation amounts of the sample table, the horizontal axis showing the percentage of the position in the radial direction of the sample table in which the bolts are disposed for the position in the radial direction of the sample table, and the vertical axis showing standard values of concave and convex of the sample table in the vertical direction occurring in a sample mounting surface of the sample table when the bolts are fastened; and

FIG. 11 is a diagram showing, a proper bolt disposition range with a deflection of the surface of the sample table taken into account, and the positions in which the pusher pins should be disposed, when the vacuum heat insulating slits are disposed in the sample table.

### DETAILED DESCRIPTION OF THE PREFERRED EMBODIMENTS

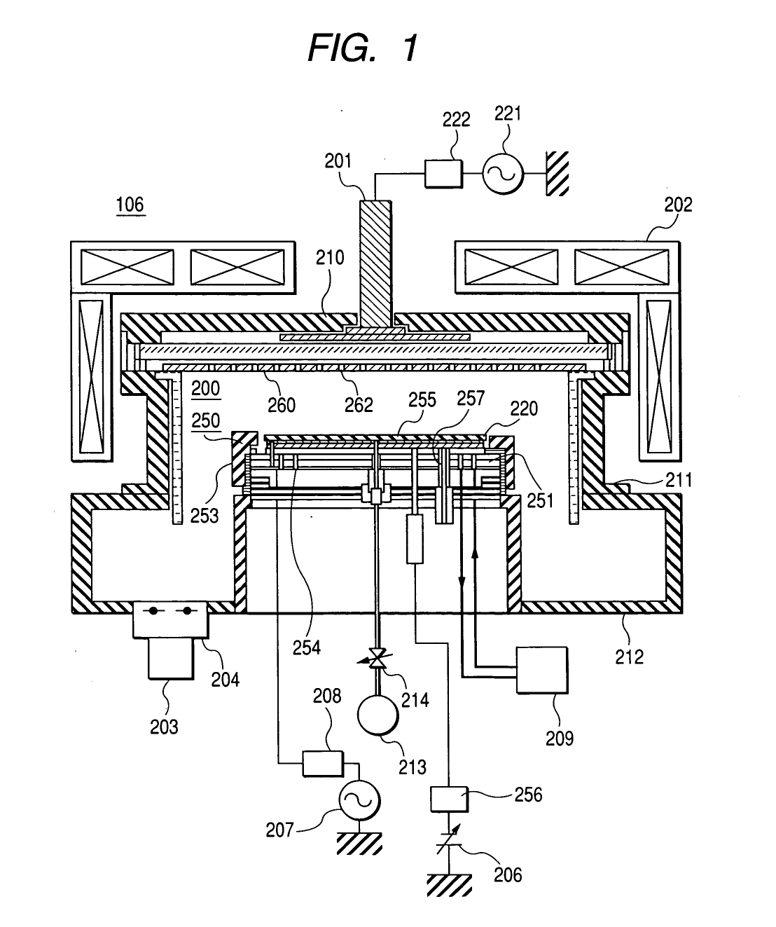

Hereinafter, one embodiment of the present invention will be described with reference to FIGS. 1 to 6.

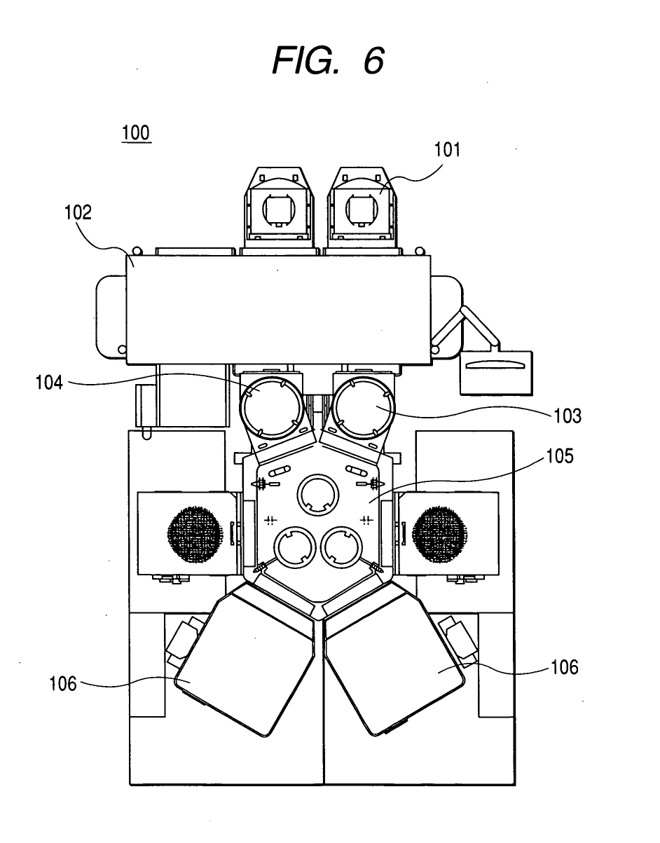

The overall construction of a vacuum processing apparatus used in a plasma processing apparatus will be described in FIG. 6. The vacuum processing apparatus 100 is composed of a sample cassette 101, an air sample transfer chamber 102, lock chambers 103 and 104, a vacuum sample transfer chamber 105, and a vacuum processing chamber 106. As described below, the present invention is characterized by the structure of a sample table (stage) for holding samples disposed within the vacuum processing chamber 106.

The following describes a concrete structure of the vacuum processing, chamber 106 with reference to FIG. 1. The vacuum processing chamber 106 includes a processing chamber 200, an antenna 201 provided above the processing chamber 200 that radiates electromagnetic waves and supplies an electric field within the processing chamber 200, and a sample table 250 that mounts a sample to be processed such as the wafer 220 in a lower portion of the processing chamber 200. The vacuum vessel 210 holds the antenna 201 and includes a sidewall 211, and a lower vessel 212 disposed below the sidewall 211. In a space between this lower vessel 212 and the sample table 250, gases, plasma, and reaction products move and are evacuated by an evacuation pump 203. In the periphery of the processing chamber 200, a magnetic field forming unit 202 having an electromagnetic coil and a yoke is disposed.

A processing gas is supplied from a gas supplying unit such as a storage tank (not shown) via a path such as a piping with a predetermined flow rate and mixture ratio to the processing chamber 200 through a through hole 262 for gas introduction provided in a shower plate 260 disposed in opposed relation above a wafer mounting surface, and pressure within the processing chamber 200 is controlled by a vacuum evacuation valve 204 including plural rotatable flaps varying an opening area of communication, and the evacuation pump 203.

Via a high frequency power source 221 and a match box 222 mounted outside the vacuum vessel 210, a high-frequency power is applied to the antenna 201 and introduced to the processing chamber 220 using the plasma. At the same time, plasma is generated by interaction between a magnetic field generated by a magnetic field generating unit 202 and the high-frequency power, and the wafer 220 is etched. The through hole 262 is disposed in a region substantially equal in area to or larger than the sample mounting surface on which the wafer 220 is mounted.

The sample table 250 includes a dielectric film 255 forming a sample mounting surface on which the wafer 220 is mounted, and a DC voltage is applied to the dielectric film 255 via a DC power supply 206 and a filter circuit 256 disposed outside the processing chamber 200, and the wafer 220 is absorbed to the sample mounting surface and held by static electricity. Furthermore, He gas is supplied to the back surface of the wafer 220 via a gas introduction adjustment valve 214 for adjusting a gas supply amount from a He gas source 213 disposed outside the processing chamber 200 to cool the wafer 220.

RF bias is applied to a metallic block 251 constituting the sample table 250 via a matching box 208 from an RF bias supply 207 disposed outside the processing chamber 200, and ion in plasma is induced onto the wafer 220 to assist etching reaction. The metallic block 251 constituting the sample table 250 is provided with a flow path 254, and a coolant is introduced to the flow path 254 by the temperature adjusting unit 209 disposed outside processing chamber 200 to control the temperature.

Specifically, although the wafer 220 receives incoming heat from plasma during processing and incoming heat by RF bias, the heat of the He gas, the dielectric film 255, and the metallic block 251 is transferred and is cooled. To electrically insulate the metallic block 251 against plasma, and to protect it from being exhausted due to sputter and etching by the plasma, a ceramic cover 253 is installed.

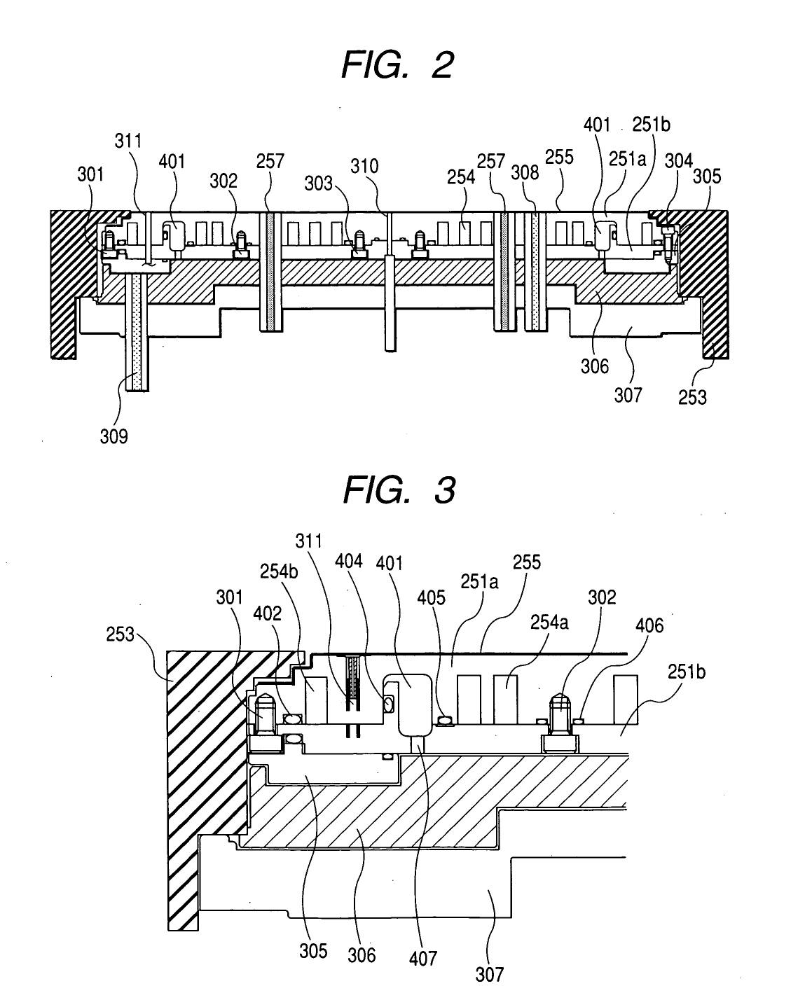

The following describes a detailed structure of the sample table 250 with reference to FIGS. 2, 3, 4, and 5. FIG. 2 shows details of the inside of the sample table 250. The metallic block 251 includes an upper metallic block 251a and a lower metallic block 251b, and by fastening them by bolts 301, 302, and 303, a heat insulating layer 401 the inside of which is evacuated is composed.

The flow path 254 through which a coolant flows is disposed in the upper metallic block 251a. He introduction paths 310 and 311 for introducing He to a wafer back surface are provided in the center and outer circumference of the metallic block 251. In this example, He introduction portions are referred to as the center and the outer circumference, but He may be introduced from other portions. The metallic block 251 has a pusher 257 for vertically conveying the wafer 220 in a middle portion, and includes an introduction terminal 308 for applying voltage to a metallic film incorporated in the dielectric film 255 to electrostatically chuck the wafer, and an introduction terminal 309 for applying a bias to a metallic block 305.

The metallic block 305 is electrically conducted to the metallic blocks 251a and 251b by a bolt 304. Instead of applying a bias to the metallic block 305, a bias may be directly applied to the metallic blocks 251a and 251b. In this embodiment, the case where the dielectric film 255 contains a metallic film, that is, a dipole electrostatic chucking apparatus is shown. However, the metallic block 251a or 251b without a metallic film, or a monopole electrostatic chucking apparatus that applies voltage to the metallic block 305 may be used. 306 designates an insulation plate and 307 designates a base.

Details of the inside of the sample table 250 are shown in FIG. 3. To feed coolants independently adjusted to different temperatures to coolant flow paths 254b and 254a to allow the metallic block 251a to efficiently generate a temperature difference, the heat insulating layer 401 is provided between the metallic blocks 251a and 251b. To obtain an ideal wafer temperature curve, it is desirable that the heat insulating layer 401 is disposed in an optimized position; the position shown in the drawing is not always required.

The heat insulating layer 401 is a ring-shaped space comprised by connection between grooves respectively disposed in the blocks 251a and 251b. Preferably, the space should be in a evacuated atmosphere to increase heat insulation effect. In this example, the metallic block 251b is provided with a hole 407 to establish a route for enabling evacuation by the evacuation pump 203. Specifically, a minor gap exists between the lower surface of the metallic block 251b and the upper surface of the insulating plate 306, and between the lower surface of the metallic block 305 and the upper surface of the insulating plate 306, and the gap communicates with the heat insulating layer 401 via the hole 407.

At the same time, the gap communicates with the space of the processing chamber 200 via gaps on the inner side of the ceramic cover 253 and on the upper surface of the insulation plate 306, and on the upper surface and side of the base 307. In other words, a sealing unit does not exist for the gaps. Therefore, as the processing chamber 200 is evacuated by the evacuation pump 203 and decompressed, the heat insulating layer 401 turns into a evacuated atmosphere via the minor gaps and the hole 407. The above-described minor gap blocks heat transfer among blocks constituting the gaps, and absorbs thermal deformation of the metallic block.

The height of the heat insulating layer 401 is almost equal to or higher than the height of the coolant grooves 254a and 254b. To further increase the heat insulation effect of the heat insulating layer 401, it is effective to enlarge the heat insulating layer 401. In this example, the height of the heat insulating layer 401 is about twice the size of the coolant grooves 254a and 254b.

The metallic block 251b below the heat insulating layer 401 is constructed to be thin and large in thermal resistance in diameter direction. To seal the insulating layer 401, O rings 404 and 405 are disposed between the metallic blocks 251a and 252b in the vicinity of the heat insulating layer 401. To seal coolant flowing through the coolant groove 254b, an O ring 402 is disposed between the metallic blocks 251a and 251b outside the coolant groove 254b, and an O ring is also disposed between the metallic block 251b and the metallic block 305. Furthermore, to seal the fastening locations of bolts 302, O rings 406 are respectively disposed in positions across from the bolt 302, and between the metallic blocks 251a and 251b. The O ring 404 composes a sealed shaft structure but may have a flat seal structure.

A ring-shaped groove is disposed in a position corresponding to the He introduction path 311 in the upper portion of the metallic block 305, and He is introduced therein from below. The He is guided to an He introduction path 311.

In the sample table 250 having such a structure, the lowest portion of strength in the metallic blocks 254a and 254b is naturally the heat insulating layer 401, and the bolts 301 & 302 are disposed across the heat insulating layer 401 each other.

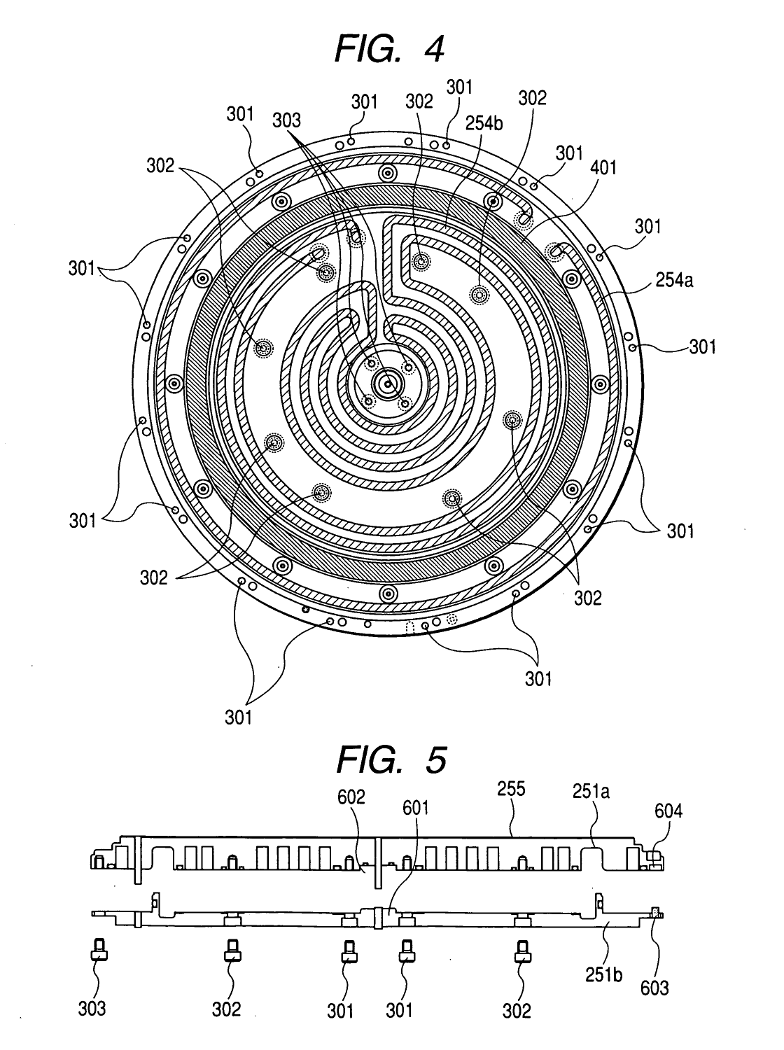

FIG. 4 shows an arranging position of the bolts 301 and 302 in a circumferential direction. In this embodiment, the heat insulating layer 401 and coolant grooves 254a, and 254b have a substantially concentric shape, and the bolts are concentrically disposed along the shape. The bolts 301 and 302 are inserted from a lower portion to an upper lower portion of the metallic block 251b, and the upper and lower metallic blocks 251a and 251b are fastened. By this construction, after the upper and lower metallic blocks 251a and 251b are integrally removed from the vacuum processing apparatus, the bolts 301 and 302 are removed to disassemble the metallic block 251a and the metallic block 251b, and a new metallic block 251a in place of the exhausted one and the old metallic block 251b may be integrally incorporated into the vacuum processing apparatus. The bolts 301 and 302 may also be inserted from an upper portion to a lower portion of the metallic block 251a to fasten the upper and lower metallic blocks 251a and 251b.

The bolts 301 are disposed in 16 locations in the circumferential direction and the bolts 302 are disposed in nine locations in the circumferential direction. However, any number of bolts for obtaining a required strength determined by a bolt size and a bolt material may be used. Furthermore, in this drawing, the bolts 303 are disposed in four locations in the central portion so that the metallic blocks 254a and 254b do not deflect in the central portion and the parallelism of the wafer mounting surface is not impaired.

FIG. 5 shows an assembly exploded view of the sample table 250 according to this embodiment. To determine a position in the radial direction of the metallic blocks 251a and 251b, the metallic block 251b is provided with a convex shape 601 and the metallic block 251a is provided with a concave shape 602 so that they are engaged with each other. To determines a position in a rotation direction, a hole 604 is provided in the metallic block 251a and a pin 603 is provided in the metallic block 251b so that the pin 603 is inserted in the hole 604. When the sprayed film 255 comes to an end of its life and is replaced by a new one, only the metallic block 251a side may be replaced, bringing about the effect of reducing running costs. For removal from the processing chamber, the metallic blocks 251a and 251b integrally fastened are removed as one.

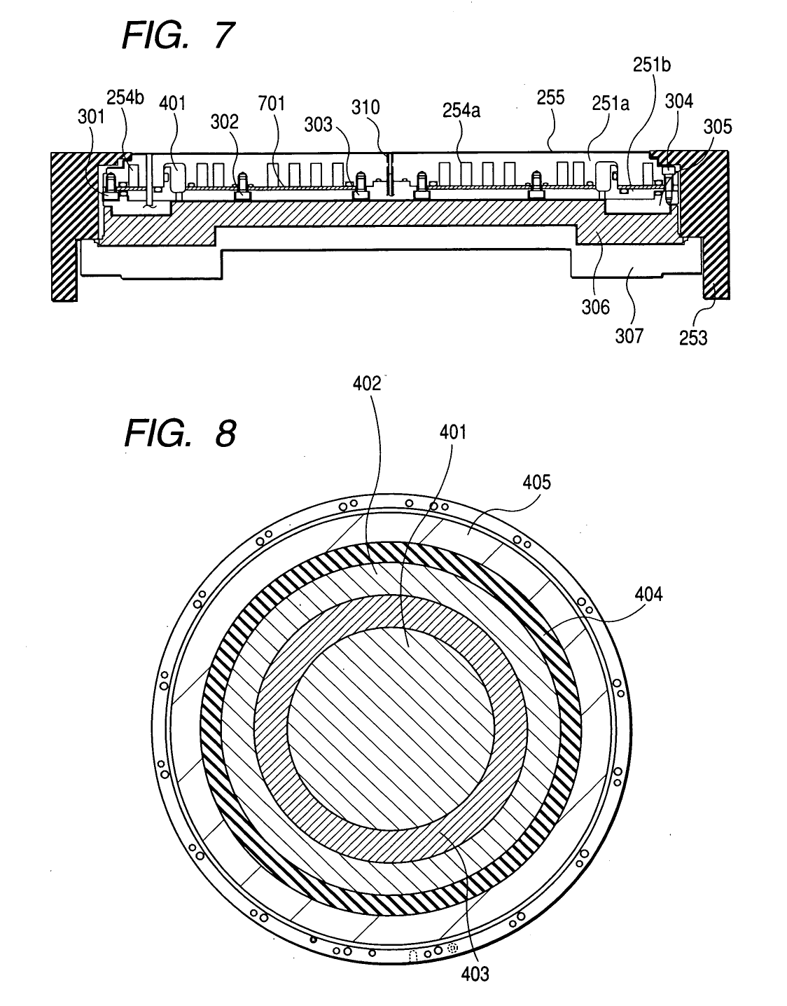

FIG. 7 shows an assembly exploded view of the sample table 250 according to a second embodiment of the present invention. The sample table 250 has a heat insulating material 701 sandwiched between the metallic blocks 251a and 251b, in which they are fastened by bolts 301, 302, and 303. The heat insulating material 701 has such a disk shape as to cover the entire lower surface of plural coolants 254a and 254b. The heat insulating material 701 may be resin, ceramic, or the like. In this structure, the effect of cooling the wafer 220 can be further increased by a coolant flowing through the coolant grooves 254a and 254b, and wafer temperature responsiveness is increased. The coolant temperature control apparatus 209 can be brought into a low capability and reduced in size and weight, bringing about the effect of lowering costs.

A means increasing heat efficiency includes changing the metallic block 251b to a member having a heat conduction suppression effect such as ceramic instead of metal.

FIG. 8 is a drawing showing schematically desirable positions in which pusher pins and bolts are disposed within a sample table in which a heat insulating layer of a evacuated atmosphere is manufactured by fastening of the present invention or a non-bonding art. Specifically, the arranging positions of the pusher pins within the sample table and the arranging positions of bolts fastening upper and lower members constituting base materials of the sample table are shown as percentage positions to the size of the radius of the wafer. Desirably, the arranging positions of the pusher pins and the bolts are within a range of 47 to 68% of the radius of the wafer.

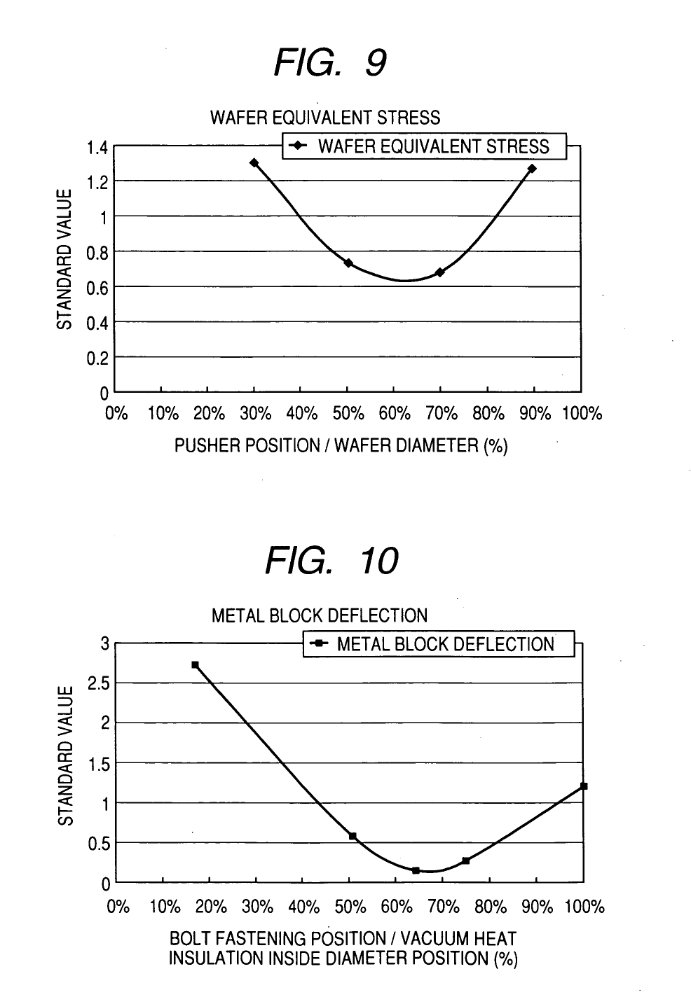

The range of arranging positions are set for reasons described with reference to FIGS. 9 to 11.

FIG. 9 is a graph showing a relation between the positions of the pusher pins in the sample table and stress occurring in the wafer. Specifically, the horizontal axis shows the percentages of the positions of the pusher pins in the radial direction of the wafer as a substrate-shaped sample to be processed for a wafer radius value, and the vertical axis shows values standardized as equivalent stress for a maximum value of stress occurring in the wafer during pushup operation of pusher pins disposed in each position (percentage), to indicate changes of the magnitude of equivalent stress for the percentage of the arranging positions of the pusher pins.

As shown in this drawing, the percentage positions of the arranging positions of the pusher pins for the wafer radius value are the minimum at about 62%. The inventors appreciated that equivalent stress generated in the wafer during pushup exerts no serious influence on the wafer by disposing the pusher pins within a range of ±15% at around 62%.

FIG. 10 shows a relation between bolt fastening positions and deflections of a sample mounting surface in the sample table in which a heat insulating layer of a evacuated atmosphere is manufactured by bolt fastening or a non-bonding method. Specifically, the horizontal axis shows the percentage of the position in the radial direction of the sample table in which the bolts are disposed for the position in the radial direction of the sample table in which the vacuum heat insulating slits of the above-described embodiment are disposed, and the vertical axis shows standard values of concave and convex (deflection deformation amount in vertical direction of an upper base material) of the sample table in the vertical direction occurring in a sample mounting surface of the sample table when the bolts are fastened, to indicate a relation between the percentage of bolt positions and standard values of deformation amounts of the sample table.

As shown in this drawing, a deflection amount of the sample table (deformation amount in vertical direction of upper member) is smaller than values in both sides in a predetermined range of the percentage of bolt fastening positions, and particularly becomes minimum in a percentage position at about 65%. The inventors appreciated that a deflection amount of the sample table occurring when upper and lower members are fastened by the bolts exerts no serious influence on the results of processing the wafer surface by disposing bolts within a range of about ±15% at around 65%.

The positions of vacuum heat insulating slits disposed within the sample table are usually disposed within a range of 70% to 85% of the cylindrical sample table in the radial direction. In this embodiment, gas is introduced from a gas introduction hole serving as a through hole disposed in a shower plate disposed above the sample to below the sample, and plasma is generated within space inside the processing chamber above the sample table to process the sample, and discharged through a space between the outer side of the sample table and the inner wall within the processing chamber. In this construction, when the distribution of reaction products adhered to the sample surface in an upper portion of the sample is taken into account, the positions of vacuum heat insulating slits are within the above-described range.

In the above-described embodiment, a processing shape of the sample surface is influenced by the distribution of the amount and density of adhesive substances such as reaction products adhered to the sample surface, and the adhesion of deposits such as the reaction product primarily depends on temperatures. Therefore, by properly adjusting the temperature of the sample, a processing shape of the sample surface is accurately adjusted. Based on the knowledge that the distribution of the reaction product within space above the sample surface is large in the center of the sample and becomes rapidly small in the outer circumference, the inventors, to make a temperature distribution within the sample table larger in the center of the sample and smaller in the outer circumference, disposes a concentric or spiral passage through which the heat exchange medium having high temperature flows in the center within the sample table, and a concentric or spiral passage through which heat exchange medium having cool temperature flows in the outer circumference, and disposes vacuum heat insulating slits between the passages for suppressing heat transfer. The inventors know that, in the construction of the above-described embodiment, the distribution of deposits on the wafer becomes smaller rapidly at the range of 70-85% and more in the radial direction of the sample table, and disposes the vacuum heat insulating slits within the range.

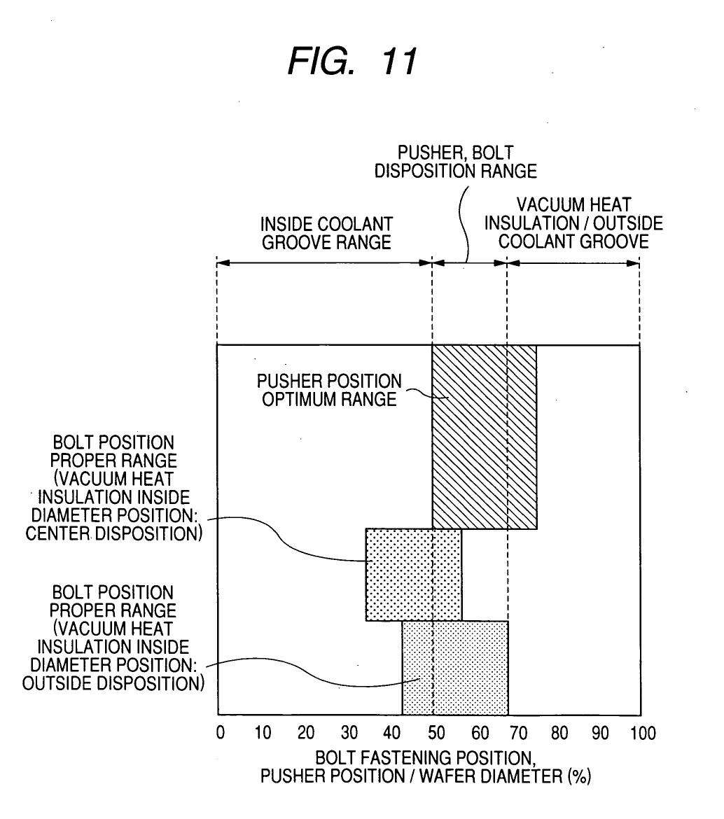

In summary, in the sample table in which a heat insulating layer evacuated is manufactured by a fastening, that is, a non-bonding method, when the vacuum heat insulating slits are disposed in the center of the sample table (e.g., position of 70%), a proper bolt disposition range with a deflection of the surface of the sample table taken into account is a range of a central portion in a vertical direction of FIG. 11, and this range is a range of 35 to 56% in a sample radial direction. When the vacuum heat insulating slits are disposed in the center of the sample table (e.g., position of 85%), a proper bolt disposition range with a deflection of the surface of the sample table taken into account is a range of a lower portion in a vertical direction of FIG. 11, and this range is a range of 42.5 to 68% in a sample radial direction.

Furthermore, a proper range to dispose the pusher pins is a range of 47 to 68% in a sample radial direction, and the range is shown in an upper portion of FIG. 11.

In this embodiment, in these ranges, the pusher pins and the bolts are disposed on a circle circumference of a same radius within the range of 47 to 68% in which a proper range of bolt disposition and a proper range of pusher pin disposition agree with each other.

In view of these points, as shown in FIG. 8, by setting the arranging positions of the pusher pins and the bolts to the range of 47 to 68% as the values of percentage positions to the size of the size of wafer radius, a deflection amount in a vertical direction of the sample table surface influenced by equivalent stress occurring in the sample and a processing shape of the sample surface can fit within a permissible range. Particularly, in this case, the pusher pins and the bolts are disposed on a circle circumference of a same radius from the center of the cylindrical sample table. Thus, the inside of the sample table is divided into regions or blocks of plural structures from the center axis to the outer circumference, parts and structures disposed within the sample table are efficiently disposed, and the structure of the sample table is simplified or miniaturized.

Specifically, in this embodiment, the pusher pins and the bolts are disposed in positions of percentage positions 47 to 68% to the wafer radius from the center axis of the sample table to the outer circumference, and a passage for a heat exchange medium is disposed in the center of the sample table across the region. The heat exchange medium in the center is not disposed to extend to the outer circumference of the sample table to surround or bypass the pusher pins or bolts. In other words, the heat exchange medium is disposed concentrically or spirally even in positions at the center of the sample table in the vicinity of the pusher pins or bolts.

The vacuum heat insulating slits are disposed from the radial direction to the outer circumference of the sample table in which the pusher pins and bolts are concentrically disposed, and a passage for heat exchange medium is disposed in the outer circumference of the sample table. The pusher pins and the bolts are disposed with a predetermined diameter, and with a margin in addition to this diameter, passages for heat exchange medium are disposed in the center and the outer circumference of the sample table. The passage for heat exchange medium at the outer circumference, like the passage at the center, is disposed concentrically or spirally without bypassing or surrounding the pusher pins or the bolts.

Thus, on the inside of the sample table, passages for heat exchange medium are disposed in the center and the outer circumference sandwiching a region in which the pusher pins and the bolts are disposed on a circle circumference of a same radius. In the region in which the pusher pins and the bolts are disposed, if space permits, or according to specifications, mechanical and electrical structures vertically disposed such as lines and connectors for energizing electrodes in an upper portion of the sample table, a socket, and a passage for gases supplied to the sample table surface can be disposed. Thus, in the above-described embodiment, the inside of the sample table includes plural concentric doughnut-shaped (or ring-shaped) regions comprising a region in which a central passage for a heat exchange medium is disposed, a region which vertically extending structures are disposed outside the region, and a region in which vacuum heat insulating slits and a passage for heat exchange medium in the outer circumference disposed outside the region are disposed.

By such the construction, efficiently disposed within the sample table, the sample table can be made small in size. Moreover, since the passage for heat exchange medium is disposed meanderingly in the radial direction from the concentric or spiral shapes because of the disposition of the vertical structures, a local bias in a temperature distribution within the sample table, an uneven temperature distribution in the circumferential direction at the center of the sample table, and an uneven processing shape are suppressed.

According to this embodiment, since the sample table has a heat insulating layer of a evacuated atmosphere manufactured by fastening, when the sprayed film has come to an end of its life and must be replaced by a new one, only the metallic block provided with the sprayed film has to be replaced, and running costs are reduced. Furthermore, since the upper and lower metallic blocks can be removed from the processing chamber in a fastened state, and the two metallic blocks can be integrally removed from the processing chamber, the replacement operation is easy.

What is claimed is:

1. A plasma processing apparatus comprising:
a processing chamber evacuated by an evacuating system;
a sample table disposed within the processing chamber in which a sample mounting surface is provided; and
pusher pins for carrying in/out a sample to the sample mounting surface,
the plasma processing apparatus further comprising:
a first disk-shaped member and a second disk-shaped member that are disposed inside the sample table and vertically connected;
an outer circumference coolant groove and an inner coolant groove that are respectively disposed in the outer circumference side and the central side of the first disk-shaped member through which coolants flow;
a ring-shaped groove disposed between the inner and outer coolant grooves for suppressing heat transfer between the inner and outer coolant grooves;
a first fastening unit that fastens the first disk-shaped member and the second disk-shaped member in the outer circumference side of the ring-shaped groove; and
a second fastening unit that fastens the first disk-shaped member and the second disk-shaped member in the inner circumference side of the ring-shaped groove,
wherein the pusher pins and the second fastening unit are disposed further in a concentric region at the inner circumference side than the ring-shaped groove with respect to the sample table, and the inner coolant groove is disposed further at the central side of the sample table than the concentric region.

2. The plasma processing apparatus according to claim 1,
wherein the concentric region is within a range of 47 to 68% of the radius of the sample.

3. The plasma processing apparatus according to claim 1 or 2, comprising a third fastening unit that fastens the first disk-shaped member and the second disk-shaped member, provided at the further central side of the sample table than the second fastening unit with the inner coolant groove therebetween.

4. The plasma processing apparatus according to claim 1 or 2,
wherein a part of the inner coolant groove is disposed between the ring-shaped groove, and the second fastening unit and the pusher pins that are disposed in the concentric region.

5. A plasma processing apparatus comprising:
a processing chamber evacuated by an evacuating system;
a sample table disposed within the processing chamber in which a sample mounting surface is provided; and
pusher pins for carrying in/out a sample to the sample mounting surface,
the plasma processing apparatus further comprising:
a first disk-shaped member and a second disk-shaped member that are disposed inside the sample table and vertically connected;
coolant grooves that are respectively disposed in the outer circumference side and the central side of the first disk-shaped member and inside which coolants flow;
a ring-shaped groove for suppressing heat transfer between these coolant grooves that is disposed between these coolant grooves; and
a fastening unit that fastens the first disk-shaped member and the second disk-shaped member respectively in a plurality of positions of the outer circumference side of the coolant groove of the outer circumference side, and in a plurality of positions of the inner circumference side of the ring-shaped groove,
wherein the fastening unit of the inner circumference side of the ring-shaped groove and the pusher pins are disposed on a circle circumference within a range of 47 to 68% of the radius of the sample.

6. A plasma processing apparatus comprising:
a processing chamber evacuated by an evacuating system;
a sample table disposed in the processing chamber that has a wafer mounted on the upper surface;
a plate that is disposed above the sample table and disposed opposite to the sample table;
a supply hole provided in the plate through which processing gases are supplied to the processing chamber; and
an evacuation apparatus that evacuates gases of the processing chamber from a space at the outer circumference side of the sample table,
the plasma processing apparatus further comprising:
two disk-shaped members that are disposed inside the sample table and vertically connected;
coolant grooves that are respectively disposed in the outer circumference side and the central side of the upper disk-shaped member through which coolants flow;
a ring-shaped groove that is disposed between these coolant grooves for suppressing heat transfer between these coolant grooves; and
a fastening unit that fastens the upper disk-shaped member and the lower disk-shaped member respectively in a plurality of positions of the outer circumference side of the coolant groove of the outer circumference side, and in a plurality of positions of the inner circumference side of the ring-shaped groove,
wherein the fastening unit of the inner circumference side of the ring-shaped groove and the pusher pins are disposed on a circle circumference within a range of 47 to 68% of the radius of the sample, and
wherein the upper disk-shaped member and the lower disk-shaped member can be removed in a fastened state from the processing chamber.

7. The plasma processing apparatus according to any one of claims 5 and 6,
wherein the coolant groove at the central side includes a plurality of circulation routes at the center of the sample table, and
wherein the plasma processing apparatus comprises a heat transfer suppressing member disposed at the lower side of the grooves of the plurality of circulation routes.

8. The plasma processing apparatus according to claim 7, comprising the coolant groove including the plurality of circulation routes between the fastening unit disposed in the inner circumference side of the ring-shaped groove and the pusher pins, and the second fastening unit.

9. A plasma processing apparatus comprising:
a processing chamber evacuated by an evacuating system;
a sample table disposed within the processing chamber in which a sample mounting surface is provided;
pusher pins for carrying in/out a sample to the sample mounting surface;
a first disk-shaped member and a second disk-shaped member that are disposed inside and vertically connected;
coolant grooves that are respectively disposed in the outer circumference side and the central side of the first disk-shaped member and inside which coolants flow;
a ring-shaped groove for suppressing heat transfer between these coolant grooves that is disposed between these coolant grooves; and
a fastening unit that fastens the first disk-shaped member and the second disk-shaped member respectively in the outer circumference side and the inner circumference side of the ring-shaped groove,
wherein the fastening unit of the inner circumference side of the ring-shaped groove and the pusher pins are disposed on a circle circumference within a range of 47 to 68% of the radius of the sample.
